(19) United States
(12) Patent Application Publication
(10) Pub. No.: US 2008/0182501 A1
(43) Pub. Date: Jul. 31, 2008

(54) FAN-FIXING STRUCTURE

(75) Inventor: Shou-Jen Yang, Taipei (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: INVENTEC CORPORATION, Taipei (TW)

(21) Appl. No.: 11/465,411

(22) Filed: Aug. 17, 2006

(51) Int. Cl. H05K 5/00; G06F 15/00

(52) U.S. Cl. 454/184

(57) ABSTRACT

A fan-fixing structure for fixing the fan and a conducting wire of the fan is provided, which includes: a fan tray, used for fixing the fan and having a wiring board extended from the fan tray, wherein the wiring board has a wire guide for the conducting wire to pass through; and at least one reinforcing rib, fastened between the wiring board and the fan tray, so as to enhance the fixing strength of the wiring board.

### BACKGROUND OF THE INVENTION

1. Field of Invention

The present invention relates to a fan-fixing structure, and more particularly, to a fan-fixing structure having a reinforcing rib on the fan tray.

2. Related Art

As the progress of the electronic science and technology, various electronic products make people's daily life become more convenient and comfortable. Especially, the working frequency of the central processor unit (CUP) in the computer industry is continuously enhanced, thus, electronic parts need heat sinks to dissipate the heat. The common heat sink is a heat-sink fan, which is fixed on the casing of the computer system through a fixing structure, so as to reduce the temperature of the computer system.

With reference to ROC Patent Publication No. M260997, a fan tray assembly of a computer heat-sink fan is disclosed, which is capable of rotating the computer heat-sink fan out of or detaching the computer heat-sink fan from the casing space. The assembly comprises: a fan tray, for assembling the heat-sink fan as a whole; a group of combining components, a first component is bonded with the fan tray, a second component is fixed on the casing to provide the assembling position for the fan tray, and the two components are bonded to make the fan tray to be rotated out of or easily detached from the casing; and a positioning component, preventing the heat-sink fan from shaking during operation, after the fan has been fixed on the casing. Compared with the locking assembly of the conventional heat-sink fan, it is easier to withdraw the heat-sink fan with a large volume out from the casing to obtain the space, thus, it is more convenient to replace and maintain other components within the casing, without detaching a number of components.

Although the fixing structure disclosed in the above patent makes the heat-sink fan withdraw out of the casing, when the heat-sink fan is re-assembled on the casing, the combining component is easily broken under a strong force applied, so it is still not perfect in usage.

Therefore, how to provide a fan-fixing structure to strengthen the supporting strength of the fan-fixing structure is still a problem to be solved by the researchers.

### SUMMARY OF THE INVENTION

Based on the above problems, a main objective of the present invention is to provide a fan-fixing structure, wherein a reinforcing rib is bonded with a wiring board on the fan tray, so as to strengthen the supporting strength of the wiring board, thus, the fan tray assemble is more firmly fixed on the casing, and the conducting wire of the fan is further fixed.

Therefore, in order to achieve the above objective, the fan-fixing structure disclosed by the present invention, used to fix the fan and the conducting wire of the fan, comprises: a fan tray, used to fix the fan and having a wiring board extended from the fan tray, wherein the wiring board has a wire guide for the conducting wire to pass through, and a positioning hole is located above the side wall of the wiring board for accommodating an extruding portion of a reinforcing rib; and at least one reinforcing rib, fastened between the wiring board and the fan tray, and having a buckling portion on the bottom of the reinforcing rib, for buckling with the wiring board, and an extruding portion on the side edge of the reinforcing rib, for passing through the positioning hole on the fan tray.

Moreover, in order to achieve the above objective, the fan-fixing structure disclosed by the present invention, used to fix the fan and the conducting wire of the fan, comprises: at least a fan; a first fan tray, having at lest a first fixing hole; a second fan tray, having at least a second fixing hole corresponding to the first fixing hole for fixing the fan by at least a fixing member, and having a wiring board extended from the second fan tray, wherein the wiring board has a wire guide for the conducting wire to pass through, and a positioning hole is located above the side wall of the wiring board, for accommodating an extruding portion of a reinforcing rib; and at least a reinforcing rib, fastened between the wiring board and the second fan tray, and having a buckling portion on the bottom of the reinforcing rib, for buckling with the wiring board, and an extruding portion on the side edge of the reinforcing rib, for passing through the positioning hole on the second fan tray.

Through using the fan-fixing structure, the supporting strength of the fixing structure on the fan tray is enhanced, which is mainly benefited from combining the reinforcing rib with the wiring board on the fan tray, so when the fan tray has been assembled on the casing, the reinforcing rib counteracts a part of the reaction force during assembling, thereby enhancing the supporting strength of the wiring board. The reinforcing rib has a threading channel to accommodate the conducting wire of the fan, so as to further achieve the overall aesthetic effect of the fan.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic stereogram of an appearance for a fan tray according to an embodiment of the present invention;

FIG. 2 is a schematic exploded stereogram of a wiring board and a reinforcing rib according to an embodiment of the present invention;

FIG. 3 is a schematic combined stereogram of the wiring board and the reinforcing rib according to an embodiment of the present invention;

FIG. 4 is a schematic exploded stereogram of a serial fan assembly and a fan tray according to an embodiment of the present invention;

FIG. 5 is a schematic combined stereogram of the serial fan assembly and the fan tray according to an embodiment of the present invention; and

FIG. 6 is a schematic exploded stereogram of the fan assembly and the casing according to an embodiment of the present invention.

### DETAILED DESCRIPTION OF THE INVENTION

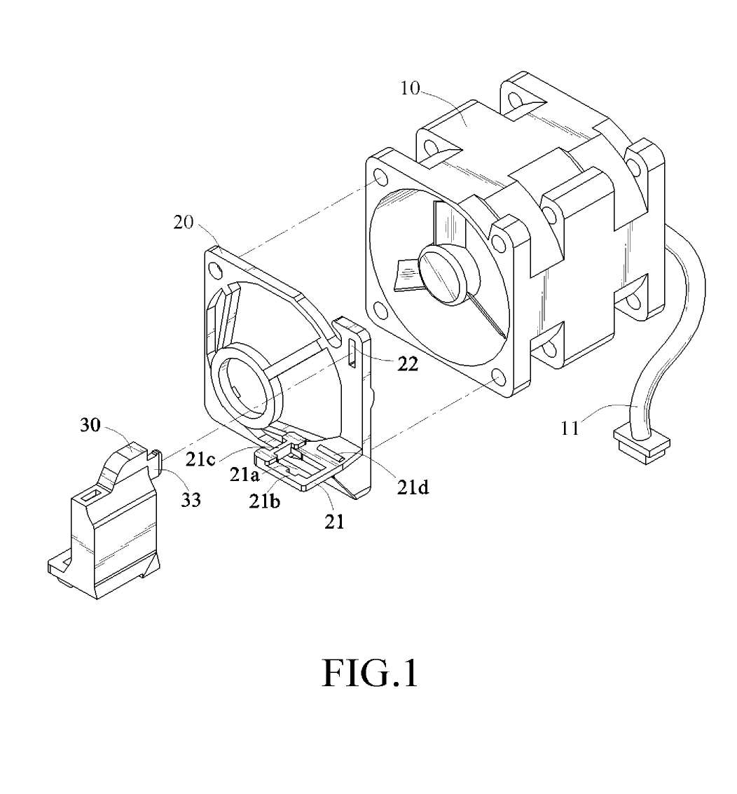

Referring to FIG. 1, it is a schematic stereogram of an appearance for a fan tray according to an embodiment of the present invention. The fan-fixing structure used for fixing the fan 10 and the conducting wire 11 comprises: a fan tray 20 and a reinforcing rib 30.

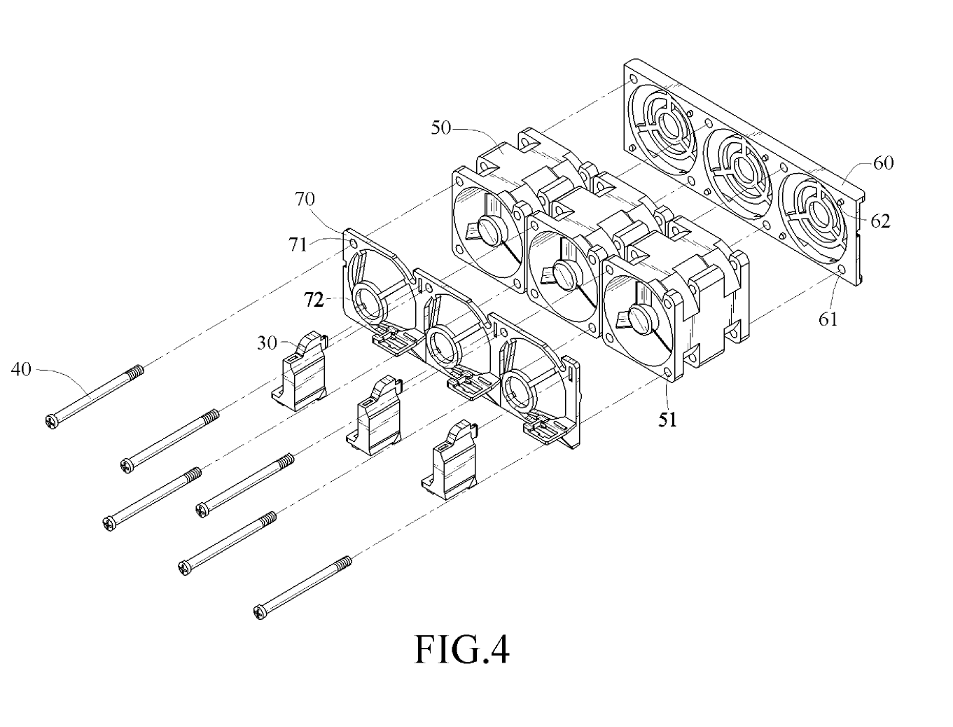

The fan 10 has a conducting wire 11 connected to the power supply, and the fan 10 is bonded with the fan tray 20 through the fixing member 40 (as shown in FIG. 4), so as to be fixed on the fan tray 20.

The fan tray 20 is used to fix the fan 10, and has a wiring board 21 extended from the fan tray 20. The wiring board 21 has a wire guide 21a for the conducting wire 11 to pass through, and a positioning hole 22 is formed above the side wall of the wiring board 21. When the reinforcing rib 30 is bonded with the fan tray 20, the positioning hole 22 is used to accommodate the extruding portion 33 of the reinforcing rib 30.

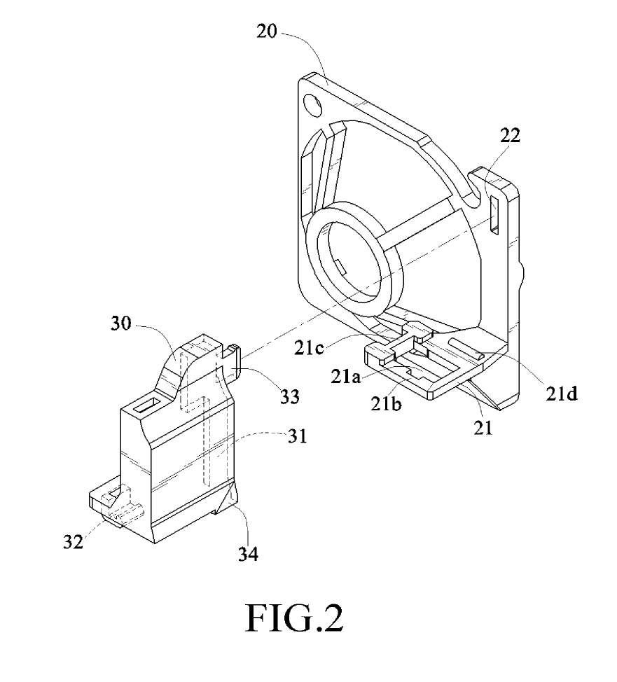

Referring to FIG. 2, it is a schematic exploded stereogram of a wiring board and a reinforcing rib according to an embodiment of the present invention. The wiring board 21 further comprises: a first snapping portion 21b, a second snapping portion 21c, and a bulging portion 21d.

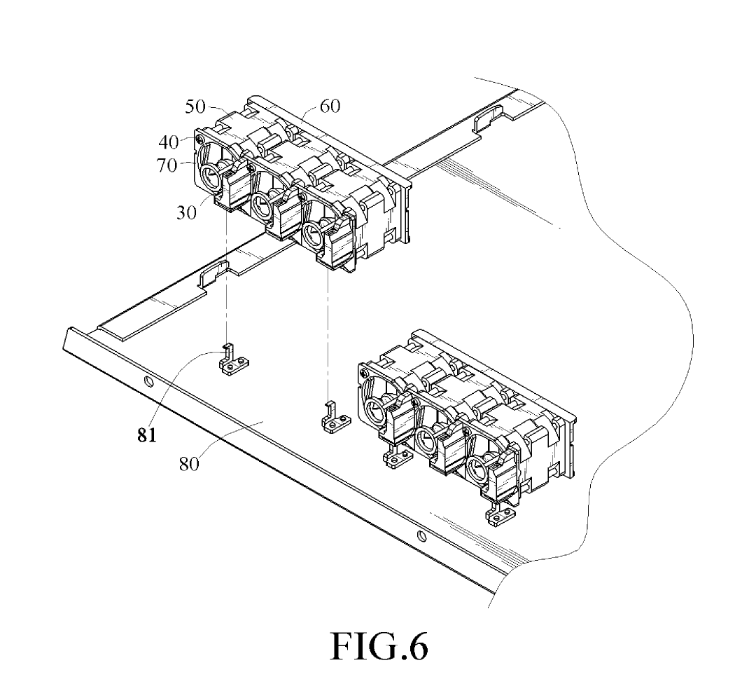

The first snapping portion 21b is formed on a side edge of the wiring board 21. When the fan tray 20 is bonded with the casing 80 (as shown in FIG. 6), the first snapping portion 21b is snapped in the buckling portion 81 of the casing.

The second snapping portion 21c is formed on the other side edge of the wiring board 21. When the reinforcing rib 30 is bonded with the wiring board 21, the second snapping portion 21c is snapped in the buckling portion 31 of the reinforcing rib 30.

The bulging portion 21d is formed on a surface of the wiring board 21, opposite to the position of the first snapping portion 21b, which is approximately in a shape of a long rectangular bulging strip. When the reinforcing rib 30 is bonded with the wiring board 21, the bulging portion 21d is used to lean against the non-slipping block 34 of the reinforcing rib 30, so as to prevent the reinforcing rib 30 from slipping.

The reinforcing rib 30 is fastened between the wiring board 21 and the fan tray 20. When the fan tray 20 is bonded with the casing 80, the reinforcing rib 30 is used to strengthen the supporting strength of the wiring board 21, wherein the reinforcing rib 30 has a threading channel 31 for the conducting wire 11 to pass through and thereby to be disposed within the wire guide 21a.

The reinforcing rib 30 further comprises: a buckling portion 32, an extruding portion 33, and a non-slipping block 34.

The buckling portion 32 is formed on a side edge of the bottom of the reinforcing rib 30 and has a hook structure with an approximately “L”-shaped side appearance. When the reinforcing rib 30 is bonded with the wiring board 21, the buckling portion 32 is used to buckle with the second snapping portion 21c of the wiring board 21.

The extruding portion 33 is formed on the side edge of the reinforcing rib 30, approximately with a shape of a long rectangular strip. When the reinforcing rib 30 is bonded with the wiring board 21, it is used to pass through the long rectangular-shaped positioning hole 22 on the fan tray 20, thus, not only achieving the effect of positioning the reinforcing rib 30, but also further strengthening the supporting strength of the wiring board 21.

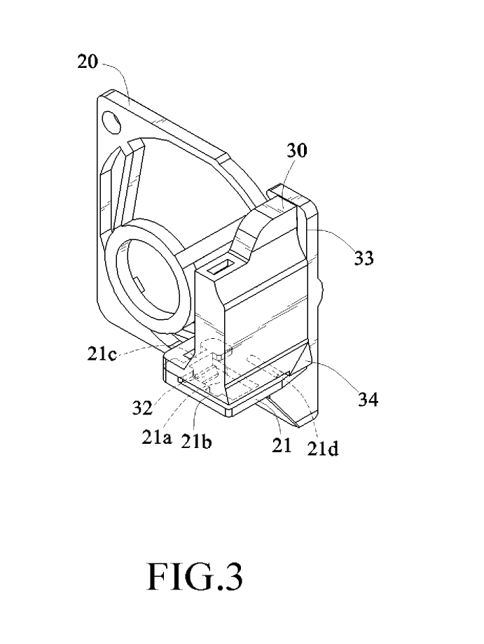

The approximately “□”-shaped non-slipping block 34 is formed on two side edges of the front edge of the bottom of the reinforcing rib 30. When the reinforcing rib 30 is bonded with the wiring board 21, the non-slipping block 34 is mutually engaged with the bulging portion 21d of the wiring board 21, so as to prevent the reinforcing rib 30 from slipping. Next, referring to FIG. 3, it is a schematic combined stereogram of the wiring board and the reinforcing rib according to an embodiment of the present invention.

Referring to FIG. 4, it is a schematic exploded view of a serial fan assembly and a fan tray fixing structure according to an embodiment of the present invention. In the drawing, three serial fan assemblies, for example, are fixed for illustration, which comprises: a serial fan assembly 50, a first fan tray 60, a second fan tray 70, a fixing member 40, and a reinforcing rib 30.

The serial fan assembly 50 is formed by sequentially arranging more than one fan. A through hole 51 is disposed at each of the four edges of the serial fan assembly 50, corresponding to the first fixing hole 61 on the first fan tray 60 and the second fixing hole 71 on the second fan tray 70. The fixing member 40 passes through the first fixing hole 61, the through hole 51, and the second fixing hole 71, so as to fix the first fan tray 60, the second fan tray 70, and the serial fan assembly 50, wherein the fixing member 40 may be a screw in practice. When the first fan tray 60, the second fan tray 70, and the serial fan assembly 50 are bonded together, the protruding portion 62 of the first fan tray 60 and the protruding portion 72 of the second fan tray 70 are engaged with the corresponding through hole 51. Therefore, the serial fan assembly 50 is fixed through the fixing member 40 by way of diagonally locking, and thereby enhancing the fixing strength of the fan tray and reducing the number of the fixing member 40 being used, so as to reduce the manufacturing cost of the fan-fixing structure.

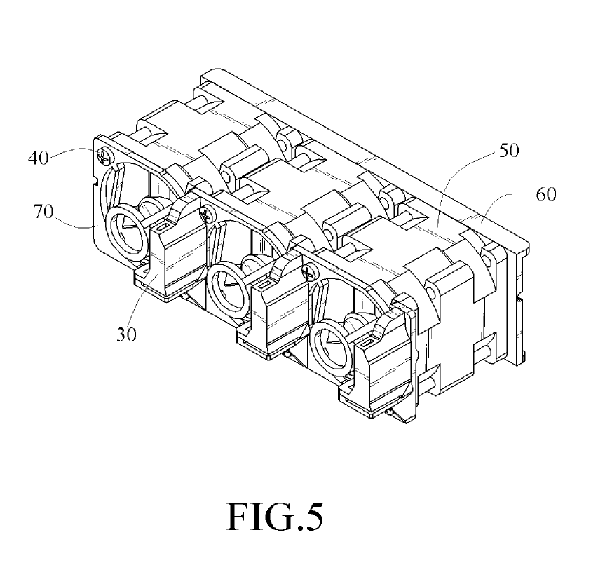

Referring to FIG. 5, it is a schematic combined view of the serial fan assembly and the fan tray fixing structure according to an embodiment of the present invention. Moreover, the structure of the reinforcing rib 30 can be known with reference to FIG. 2, which thus will not be described herein any more.

Referring to FIG. 6, it is a schematic exploded stereogram of the fan assembly and the casing according to an embodiment of the present invention. When the serial fan assembly 50 is bonded with the casing 80, the wiring board 20 on the second fan tray 70 is mutually buckled with the buckling portion 81 of the casing. Since the wiring board 20 is bonded with the reinforcing rib 30, when the serial fan assembly 50 is fixed on the casing 80 under a force applied downward, the reaction force generated by the buckling portion 81 of the casing is partly counteracted by the fixing structure of the reinforcing rib 30 and the second fan tray 70, so as to enhance the supporting strength of the wiring board 20 on the second fan tray. The threading channel 31 of the reinforcing rib 30 may accommodate the conducting wire of the serial fan assembly 50 to pass there through, so as to further make the conducting wire of the serial fan assembly 50 be more ordered, and thereby enhancing the overall aesthetic effect.

Through using such a fan-fixing structure, the supporting strength of the fixing structure on the fan tray is enhanced, which is mainly benefited from bonding the reinforcing rib with the wiring board on the fan tray, so when the fan tray has been assembled on the casing, the reinforcing rib counteracts a part of the reaction force during assembling, thereby enhancing the supporting strength of the wiring board. The reinforcing rib has a threading channel to accommodate the conducting wire of the fan, so as to further achieve the overall aesthetic effect of the fan.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A fan-fixing structure, used to fix a fan and a conducting wire of the fan, comprising:
a fan tray, for fixing the fan, and having a wiring board extended from the fan tray, wherein the wiring board has a wire guide for the conducting wire to pass through; and
at least a reinforcing rib, fastened between the wiring board and the fan tray.

2. The fan-fixing structure as claimed in claim 1, wherein the reinforcing rib has a threading channel for the conducting wire to pass through and thereby to be disposed within the wire guide.

3. The fan-fixing structure as claimed in claim 1, wherein the reinforcing rib comprises:
a buckling portion, formed on the bottom of the reinforcing rib, for buckling with the wiring board; and
an extruding portion, formed on the side edge of the reinforcing rib, for passing through a positioning hole on the fan tray.

4. The fan-fixing structure as claimed in claim 3, wherein the wiring board further comprises:
a first snapping portion, for snapping in a casing; and
a second snapping portion, for snapping in the buckling portion.

5. The fan-fixing structure as claimed in claim 1, wherein a bulging portion is formed on the wiring board, for leaning against the reinforcing rib, so as to prevent the reinforcing rib from slipping.

6. The fan-fixing structure as claimed in claim 5, wherein a non-slipping block is formed on the bottom of the reinforcing rib, for mutually engaging with the bulging portion, so as to prevent the reinforcing rib from slipping.

7. A fan-fixing structure, used to fix at least a fan and a conducting wire of the fan, wherein the fan has at least a through hole, comprising:
a first fan tray, having at least a first fixing hole;
a second fan tray, having at least a second fixing hole corresponding to the first fixing hole, and a wiring board extended from the second fan tray, wherein the wiring board has a wire guide for the conducting wire to pass through;
at least a fixing member, passing through the first fixing hole, the through hole, and the second fixing hole, for fixing the fan in the first fan tray and the second fan tray; and
at least a reinforcing rib, fastened between the wiring board and the fan tray.

8. The fan-fixing structure as claimed in claim 7, wherein the reinforcing rib has a threading channel for the conducting wire to pass through and thereby to be disposed within the wire guide.

9. The fan-fixing structure as claimed in claim 7, wherein the reinforcing rib comprises:
a buckling portion, formed on the bottom of the reinforcing rib, for buckling with the wiring board; and
an extruding portion, formed on the side edge of the reinforcing rib, for passing through a positioning hole on the second fan tray.

10. The fan-fixing structure as claimed in claim 9, wherein the wiring board comprises:
a first snapping portion, for snapping in a casing; and
a second snapping portion, for snapping in the buckling portion.

11. The fan-fixing structure as claimed in claim 7, wherein a bulging portion is formed on the wiring board, for leaning against the reinforcing rib, so as to prevent the reinforcing rib from slipping.

12. The fan-fixing structure as claimed in claim 11, wherein a non-slipping block is formed on the bottom of the reinforcing rib, for mutually engaging with the bulging portion, so as to prevent the reinforcing rib from slipping.

13. The fan-fixing structure as claimed in claim 7, wherein the fixing member is a screw.

14. The fan-fixing structure as claimed in claim 7, wherein the first fan tray and the second fan tray have at least a protruding portion to be bonded with the through hole.
